(19) United States
(12) Patent Application Publication
(10) Pub. No.: US 2019/0393904 A1
(43) Pub. Date: Dec. 26, 2019

(54) MULTIPATH SWITCH CIRCUIT, CHIP AND COMMUNICATION TERMINAL

(71) Applicant: Vanchip (Tianjin) Technology Co., Ltd., Tianjin (CN)

(72) Inventor: Sheng LIN, Tianjin (CN)

(21) Appl. No.: 15/780,244

(22) PCT Filed: Nov. 30, 2016
(86) PCT No.: PCT/CN2016/108173

§ 371 Date: Feb. 19, 2019

(30) Foreign Application Priority Data
Dec. 1, 2015 (CN) 201510870142.8

(51) Int. Cl. H04B 1/00; H03K 17/94; H04B 1/10

(52) U.S. Cl. CPC H04B 1/006; H04B 1/1081; H03K 17/94

(57) ABSTRACT

A multipath switch circuit, a chip comprising the multipath switch circuit, and a communication terminal comprising the multipath switch circuit or the chip. The multipath switch circuit is applied to a solid antenna switch, comprising common gate switch transistor groups which are connected in series and arranged between a radio frequency signal input end (RFin) and a signal output end (RFout), and a source-drain bias resistance network (101) which is arranged between a source electrode (S) of the first switch transistor connected to the signal input end (RFin) and a drain electrode (D) of the last switch transistor connected to the signal output end (RFout).

### BACKGROUND

### Technical Field

The present invention relates to a multipath switch circuit used in a solid antenna switch, a chip including the multipath switch circuit, and a communication terminal, and belongs to the field of integrated circuit technologies.

### Related Art

Currently, solid antenna switches have been widely applied to wireless communication front end modules or multipath antenna switch modules. In rapidly developed multimode and multiband smartphone systems, the number of modes thereof and the number of bands thereof are constantly increasing. This requires for an increasing number of paths in antenna switches, and the differential loss and linear characteristics thereof also need to be kept or even improved.

In the prior art, a structural block diagram of a typical multipath antenna switch is shown in FIG. 1. When a switch of one of the paths is connected, switches of other paths are simultaneously disconnected. In this way, only a radio frequency signal connected to this path can be transmitted from an input end (RFin_n) to an output end (RFout). In a case of an ideal switch, the impedance of a connected path is zero, but the impedance of a disconnected path is infinite. Therefore, an input signal is completely transmitted from the input end (RFin_n) to the output end (RFout). No power is consumed on the connected path and no input signal is leaked to another signal input end by using the disconnected path.

From the perspective of the working principle, a principle diagram of any multipath switch circuit in a multipath antenna switch is shown in FIG. 2. The multipath switch circuit includes common gate switch transistor (also referred to as: field-effect transistor) groups that are connected in series and a control circuit thereof. The reason why the common gate switch transistor groups consisting of a plurality of switch transistors are disposed herein is that a breakdown voltage of an existing single switch transistor is far less than amplitude of a radio frequency signal in wireless mobile communication. Therefore, the breakdown voltage needs to be increased through series connection of a plurality of switch transistors, so as to be applicable to the radio frequency signal in the wireless mobile communication. In this switch circuit, a source electrode of a first switch transistor in the common gate switch transistor groups that are connected in series is connected to an input end of a radio frequency signal, and a drain electrode of a last switch transistor is connected to an output end of the radio frequency signal. Gates of the switch transistors are together connected to a voltage-variable control signal end, so that the switch transistors simultaneously switch between connected and disconnected states.

In the multipath switch circuit shown in FIG. 2, when each switch transistor is connected, a channel between a source electrode and a drain electrode thereof is opened. The equivalent open resistance of the channel depends on the selected process of an integrated circuit and a gate width of the transistor. A large number of switch transistors that are connected in series indicates larger equivalent resistance of the channel of the switch transistors, and a greater effect on the differential loss of the switch. This requires to accordingly increase the gate widths of the transistors to reduce the equivalent resistance of the channel. In addition, on one hand, when each switch transistor is connected, there is parasitic capacitance between a source electrode and a gate and between a drain electrode and the gate of the switch transistor. Consequently, some of radio frequency signals are leaked from the source electrode and the drain electrode to the gate and the differential loss characteristics of the switch are affected. On the other hand, when the switch transistor is disconnected, a channel between the source electrode and the drain electrode thereof is closed, but parasitic capacitance also exists between the source electrode and the drain electrode, and the linear characteristics of the switch are also affected.

In the prior art, for a given process of an integrated circuit, although the differential loss of the switch can be reduced and the linear characteristics of the switch can be increased by increasing the gate width of the transistor, because of limitation of the area of a chip, that is, limitation of design costs, and because of the reason of parasitic capacitance in a circuit layout, the improvement in performance gradually approaches saturation. On the other hand, although currently a lot of semiconductor manufacturers are devoted to the development of novel processes and switch devices, the development period thereof is long and the costs are high.

### SUMMARY

With respect to the deficiencies of the prior art, the technical problem to be resolved by the present invention is to provide a multipath switch circuit, a chip, and a communication terminal, so that linear characteristics of a path switch of a solid antenna switch can be effectively improved.

According to one aspect of embodiments of the present invention, a multipath switch circuit is disposed. The multipath switch circuit is applied to a solid antenna switch, and includes: common gate switch transistor groups that are connected in series and disposed between a radio frequency signal input end and a signal output end, and the multipath switch circuit further includes: a source-drain bias resistance network disposed between a source electrode of a first switch transistor connected to the signal input end and a drain electrode of a last switch transistor connected to the signal output end.

Preferably, the source-drain bias resistance network includes: several resistors that have a number the same as that of switch transistors in the common gate switch transistor groups and that have one-to-one correspondence with the switch transistors, where the resistors are disposed between source electrodes and drain electrodes of the corresponding switch transistors in a parallel manner.

Preferably, the multipath switch circuit further includes: a gate bias resistance network disposed between a gate of each switch transistor in the common gate switch transistor groups and an external gate control end.

More preferably, the gate bias resistance network includes: several separate gate bias resistors that have a number the same as that of switch transistors in the common gate switch transistor groups and that have one-to-one correspondence with the switch transistors, where one end of each separate gate bias resistor is connected to a gate of a corresponding switch transistor, and the other end is connected to the external gate control end.

Further, that the other end of each separate gate bias resistor is connected to an external gate control end includes:

disposing a first common gate bias resistor and a second common gate bias resistor; and

dividing the several separate gate bias resistors into two groups, where in one group, the other end of the separate gate bias resistor is connected to the external gate control end by using the first common gate bias resistor, and in the other group, the other end of the separate gate bias resistor is connected to the external gate control end by using the second common gate bias resistor.

Furthermore, the common gate switch transistor group has an even number of switch resistors; and the several separate gate bias resistors are equally divided into two groups.

That the several separate gate bias resistors are equally divided into two groups is specifically:

grouping the separate gate bias resistors connected to gates of a first half of the switch transistors into one group; and

grouping the separate gate bias resistors connected to gates of a second half of the switch transistors into one group.

That the several separate gate bias resistors are equally divided into two groups is specifically:

grouping the separate gate bias resistors connected to gates of switch transistors at odd-numbered positions into one group; and

grouping the separate gate bias resistors connected to gates of switch transistors at even-numbered positions into one group.

According to another aspect of the embodiments of the present invention, the present invention further discloses a chip, including any multipath switch circuit in the foregoing embodiments.

According to still another aspect of the embodiments of the present invention, the present invention further discloses a communication terminal, including any multipath switch circuit in the foregoing embodiments or the chip in the foregoing embodiments.

Compared with the prior art, the multipath switch circuit provided in the present invention has the following advantages:

(1) based on the existing device processes and switch circuit structures, the differential loss of the multipath antenna switch can be effectively improved by using concise lines and methods, and the linear characteristics of the switch can be further improved by changing the symmetry properties of direct current bias points; and

(2) compared with the conventional design, the chip area may be not additionally occupied while the performance is improved, so that the costs are effectively controlled.

### BRIEF DESCRIPTION OF THE DRAWINGS

FIG. 1 is a structural block diagram of a multipath antenna switch;

FIG. 2 is a principle diagram of a multipath switch circuit used in an antenna switch;

FIG. 3 is a principle diagram of a multipath switch circuit according to Embodiment 1 of the present invention;

FIG. 4 is a principle diagram of a multipath switch circuit according to Embodiment 2 of the present invention;

FIG. 5 is a principle diagram of a multipath switch circuit according to Embodiment 3 of the present invention; and

FIG. 6 is a principle diagram of a multipath switch circuit according to Embodiment 4 of the present invention.

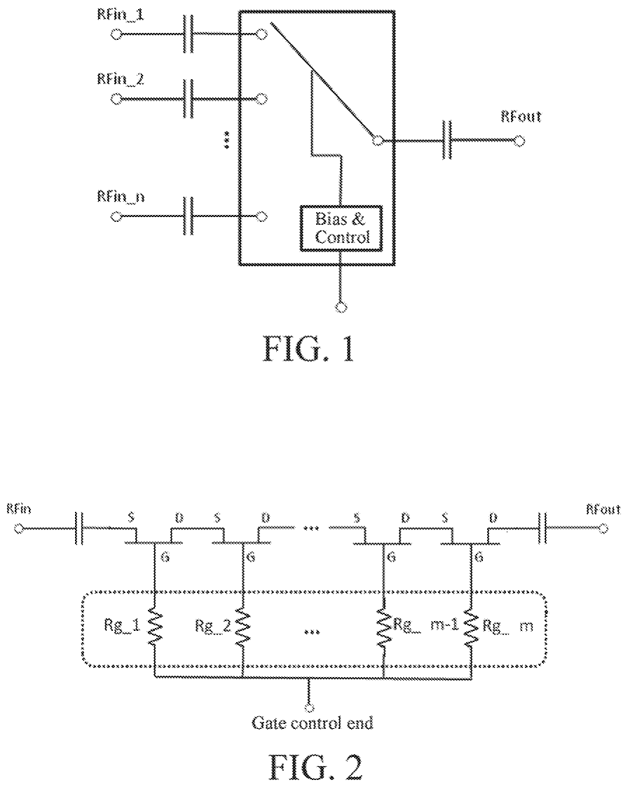

### DETAILED DESCRIPTION

In the present invention, the linear characteristics and/or the differential loss characteristics of a switch are improved by adding a source-drain bias resistance network and/or a gate bias resistance network to common gate switch transistor groups in a multipath switch circuit in the prior art.

The following further describes the technical content of the present invention with reference to the accompanying drawings and specific embodiments.

### Embodiment 1

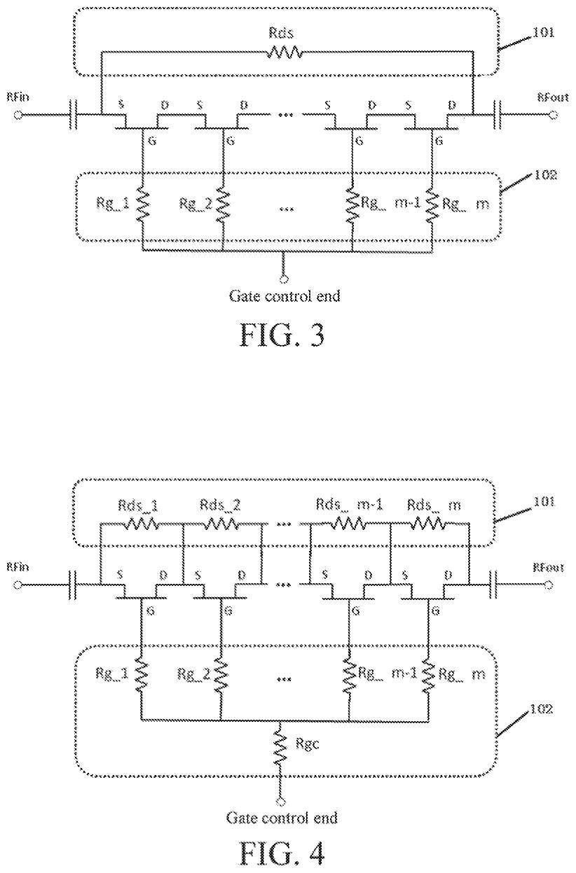

Referring to FIG. 3, FIG. 3 is a principle diagram of a multipath switch circuit according to Embodiment 1 of the present invention. The multipath switch circuit includes: common gate switch transistor groups that are connected in series, a source-drain bias resistance network 101, and a gate bias resistance network 102.

In the common gate switch transistor groups, a source electrode of a first switch transistor is connected to a radio frequency signal input end RFin of a switch path by using a DC blocking capacitor, and a drain electrode of a last switch transistor is connected to a radio frequency signal output end RFout of the switch path by using a DC blocking capacitor. Drain electrodes and source electrodes of other adjacent switch transistors in the common gate switch transistor groups are sequentially connected in series.

The source-drain bias resistance network 101 is disposed between the source electrode of the first switch transistor and the drain electrode of the last switch transistor. In Embodiment 1 of the present invention, the source-drain bias resistance network 101 includes high-impedance resistors Rds that are connected in parallel between the source electrode of the first switch transistor and the drain electrode of the last switch transistor.

The gate bias resistance network 102 is disposed between a gate of each switch transistor in the common gate switch transistor groups and an external gate control end. In Embodiment 1 of the present invention, the gate bias resistance network 102 includes: several separate gate bias resistors Rg_1, Rg_2, . . . , Rg_m that have a number the same as that of switch transistors in the common gate switch transistor groups and that have one-to-one correspondence with the switch transistors. One end of each separate gate bias resistor is connected to a gate of a corresponding switch transistor, and the other end is connected to the external gate electrode control end. That is, as shown in FIG. 3, the gate of the first switch transistor is connected to the separate gate bias resistor Rg_1, the gate of the second switch transistor is connected to the separate gate bias resistor Rg_2, . . . , and the other end of each one of these separate gate bias resistors Rg_1, Rg_2, . . . , Rg_m is directly connected to the external gate control end.

In view of this, in Embodiment 1 of the present invention, when each switch transistor is connected, although there is parasitic capacitance between a source electrode and a gate and between a drain electrode and the gate of each switch transistor, the differential loss characteristics of the switch are effectively improved because the gate bias resistance network 102 is disposed. On the other hand, when each switch transistor is disconnected, a channel between the source electrode and the drain electrode thereof is closed. Although parasitic capacitance also exists between the source electrode and the drain electrode, the symmetry of direct current bias points of the source electrode and the drain electrode of the switch transistor is kept because the source-drain bias resistance network 101 is disposed, so that the linear characteristics thereof are improved.

### Embodiment 2

Referring to FIG. 4, FIG. 4 is a principle diagram of a multipath switch circuit according to Embodiment 2 of the present invention. Similar to Embodiment 1, the multipath switch circuit includes: common gate switch transistor groups that are connected in series, a source-drain bias resistance network 101, and a gate bias resistance network 102. However, for the source-drain bias resistance network 101, the gate bias resistance network 102 is further improved with respect to Embodiment 1.

The source-drain bias resistance network 101 includes: several resistors (Rds_1, Rds_2, . . . , Rds_m) that have a number the same as that of switch transistors in the common gate switch transistor groups and that have one-to-one correspondence with the switch transistors, where the resistors are disposed between source electrodes and drain electrodes of the corresponding switch transistors in a parallel manner and are sequentially connected in series.

The gate bias resistance network 102 includes: several separate gate bias resistors Rg_1, Rg_2, . . . , Rg_m that have a number the same as that of switch transistors in the common gate switch transistor groups and that have one-to-one correspondence with the switch transistors. One end of each separate gate bias resistor is connected to a gate of a corresponding switch transistor, and the other end is connected to a common gate bias resistor Rgc. That is, as shown in FIG. 4, the gate of the first switch transistor is connected to one end of the separate gate bias resistor Rg_1, the gate of the second switch transistor is connected to one end of the separate gate bias resistor Rg_2, . . . , and the other end of each one of the separate gate bias resistors Rg_1, Rg_2, . . . , Rg_m is directly connected to one end of the common gate bias resistor Rgc. The other end of the common gate bias resistor Rgc is connected to the external gate control end.

Obviously, in Embodiment 2 of the present invention, resistors with a quantity the same as that of switch transistors connected in series exist in the source-drain bias resistance network 101, and each resistor is connected in parallel to each switch transistor. In this case, the resistances of the resistors (Rds_1, Rds_2, . . . , Rds_m) can be obviously less than the resistances of the resistors (Rds) in Embodiment 1. Therefore, compared with Embodiment 1, a source-drain voltage of each switch transistor recovers more rapidly when the switch switches from connection to disconnection, so that the objective of rapidly recovering the symmetry of direct current bias points can be achieved. On the other hand, because when the switch is connected, separate gate bias resistors of all the switch transistors are equivalent to a shunt resistor, in Embodiment 2 of the present invention, the external resistance can be improved by connecting, in series, a common gate bias resistor Rgc to the shunt resistor, thereby improving the efficiency of gate equivalent alternating current impedance.

### Embodiment 3

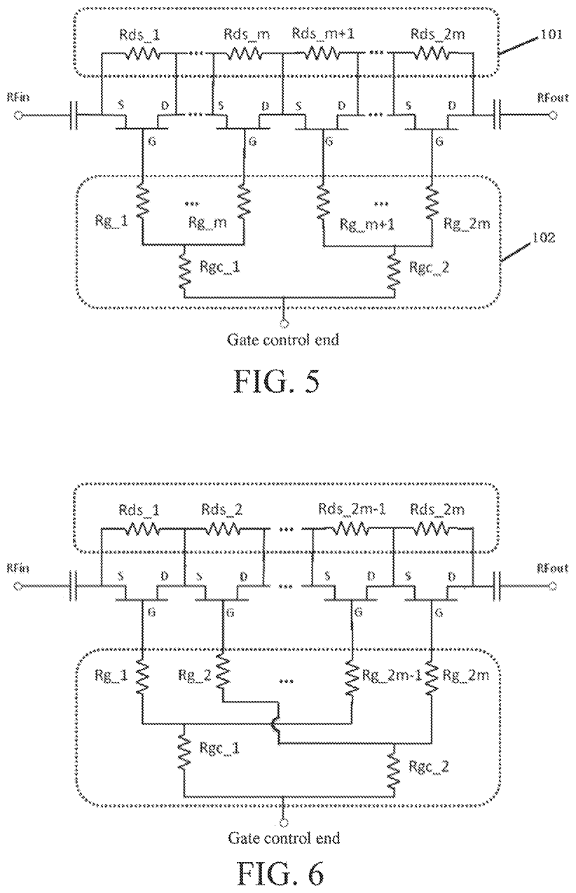

Referring to FIG. 5, FIG. 5 is a principle diagram of a multipath switch circuit according to Embodiment 3 of the present invention. Similar to Embodiment 2, the multipath switch circuit includes: common gate switch transistor groups that are connected in series, a source-drain bias resistance network 101, and a gate bias resistance network 102. However, the gate bias resistance network 102 is further improved with respect to Embodiment 2.

The gate bias resistance network 102 includes: several separate gate bias resistors Rg_1, . . . , Rg_m, Rg_m+1, . . . , Rg_2m that have a number the same as that (2m) of switch transistors in the common gate switch transistor groups and that have one-to-one correspondence with the switch transistors, and a first common gate bias resistor Rgc_1 and a second common gate bias resistor Rgc_2. One end of each separate gate bias resistor is connected to a gate of a corresponding switch transistor, and the several separate gate bias resistors are divided into two groups: the separate gate bias resistors (Rg_1, . . . , Rg_m) connected to gates of a first half of the switch transistors are grouped into one group; and the separate gate bias resistors (Rg_m+1, . . . , Rg_2m) connected to gates of a second half of the switch transistors are grouped into one group; in addition, the other end of each of the two groups of separate gate bias resistors is separately connected to one end of the first common gate bias resistor Rgc_1 and one end of the second common gate bias resistor Rgc_2, and the other end of the first common gate bias resistor Rgc_1 and the other end of the second common gate bias resistor Rgc_2 are connected to the external gate control end.

In Embodiment 3 of the present invention, the efficiency of gate equivalent alternating current impedance can be further improved by improving the structural arrangement of the gate bias resistance network, and the linear characteristics of the switch can be further improved by changing the symmetry of direct current bias points.

### Embodiment 4

Referring to FIG. 6, FIG. 6 is a principle diagram of a multipath switch circuit according to Embodiment 4 of the present invention. Similar to Embodiment 2, the multipath switch circuit includes: common gate switch transistor groups that are connected in series, a source-drain bias resistance network 101, and a gate bias resistance network 102. However, the gate bias resistance network 102 is further improved with respect to Embodiment 2.

The gate bias resistance network 102 includes: several separate gate bias resistors Rg_1, Rg_2, Rg_2m−1, . . . , Rg_2m that have a number the same as that (2m) of switch transistors in the common gate switch transistor groups and that have one-to-one correspondence with the switch transistors, and a first common gate bias resistor Rgc_1 and a second common gate bias resistor Rgc_2. One end of each separate gate bias resistor is connected to a gate of a corresponding switch transistor, and the several separate gate bias resistors are divided into two groups: the separate gate bias resistors (Rg_1, . . . , Rg_2m−1) connected to gates of switch transistors at odd-numbered positions are grouped into one group; and the separate gate bias resistors (Rg_2, . . . , Rg_2m) connected to gates of switch transistors at even-numbered positions are grouped into one group; in addition, the other end of each of the two groups of separate gate bias resistors is separately connected to one end of the first common gate bias resistor Rgc_1 and one end of the second common gate bias resistor Rgc_2, and the other end of the first common gate bias resistor Rgc_1 and the other end of the second common gate bias resistor Rgc_2 are connected to the external gate control end.

In view of this, in Embodiment 4 of the present invention, similar to Embodiment 3 of the present invention, the efficiency of gate equivalent alternating current impedance can be further improved by improving the structural arrangement of the gate bias resistance network, and the linear characteristics of the switch can be further improved by changing the symmetry of direct current bias points.

In addition, the following points may further be supplemented to the foregoing embodiments:

(1) in the foregoing Embodiment 3 and Embodiment 4, two preferable implementations of a gate bias resistance network are actually provided; in other embodiments, several separate gate bias resistors may also be grouped in other manners. However, preferably, the several separate gate bias resistors are equally divided into two groups. The manner of equal division is not limited to all the embodiments mentioned above;

(2) because the symmetry of an integrated circuit layout has an inhibiting effect for generation of harmonics, preferably, there is usually an even number of switch transistors in common gate switch transistor groups that are connected in series; and

(3) in other embodiments, the source-drain bias resistance network and the gate bias resistance network that are listed above may be randomly selected for use in combination or may be alternatively used according to actual situations without being limited to the combination of the foregoing embodiments.

Therefore, the multipath switch circuit provided in the embodiments of the present invention has the following advantages:

(1) based on the existing device processes and switch circuit structures, the differential loss of the multipath antenna switch can be effectively improved by using concise lines and methods, and the linear characteristics of the switch can be further improved by changing the symmetry properties of direct current bias points; and

(2) compared with the conventional design, the chip area may be not additionally occupied while the performance is improved, so that the costs are effectively controlled.

### Embodiment 5

The present invention further provides a chip, including any multipath switch circuit in the foregoing embodiments.

### Embodiment 6

The present invention further provides a communication terminal, including any multipath switch circuit in the foregoing embodiments or the chip in the foregoing embodiments.

The foregoing describes, in detail, the multipath switch circuit, the chip, and the communication terminal that are provided in the present invention. For a person of ordinary skill in the art, any obvious modification made to the present invention without departing from the essential spirit of the present invention constitutes infringement on the patent right of the present invention, and corresponding legal liabilities shall be born.

1. A multipath switch circuit, applied to a solid antenna switch, and comprising common gate switch transistor groups that are connected in series and disposed between a radio frequency signal input end and a signal output end, and further comprising:
a source-drain bias resistance network disposed between a source electrode of a first switch transistor connected to the signal input end and a drain electrode of a last switch transistor connected to the signal output end.

2. The multipath switch circuit according to claim 1, wherein the source-drain bias resistance network comprises:
several resistors that have a number the same as that of switch transistors in the common gate switch transistor groups and that have one-to-one correspondence with the switch transistors, wherein the resistors are disposed between source electrodes and drain electrodes of the corresponding switch transistors in a parallel manner.

3. The multipath switch circuit according to claim 1, further comprising:
a gate bias resistance network disposed between a gate of each switch transistor in the common gate switch transistor groups and an external gate control end.

4. The multipath switch circuit according to claim 3, wherein the gate bias resistance network comprises:
several separate gate bias resistors that have a number the same as that of switch transistors in the common gate switch transistor groups and that have one-to-one correspondence with the switch transistors, wherein one end of each separate gate bias resistor is connected to a gate of a corresponding switch transistor, and the other end is connected to the external gate control end.

5. The multipath switch circuit according to claim 4, wherein
a first common gate bias resistor and a second common gate bias resistor are disposed; and
the several separate gate bias resistors are divided into two groups; in one group, the other end of the separate gate bias resistor is connected to the external gate control end by using the first common gate bias resistor, and in the other group, the other end of the separate gate bias resistor is connected to the external gate control end by using the second common gate bias resistor.

6. The multipath switch circuit according to claim 5, wherein
the common gate switch transistor group has an even number of switch resistors; and
the several separate gate bias resistors are equally divided into two groups.

7. The multipath switch circuit according to claim 6, wherein that the several separate gate bias resistors are equally divided into two groups is specifically:
grouping the separate gate bias resistors connected to gates of a first half of the switch transistors into one group; and
grouping the separate gate bias resistors connected to gates of a second half of the switch transistors into one group.

8. The multipath switch circuit according to claim 6, wherein that the several separate gate bias resistors are equally divided into two groups is specifically:
grouping the separate gate bias resistors connected to gates of switch transistors at odd-numbered positions into one group; and
grouping the separate gate bias resistors connected to gates of switch transistors at even-numbered positions into one group.

9-10. (canceled)
